(19) United States
(12) Patent Application Publication
(10) Pub. No.: US 2008/0035607 A1
(43) Pub. Date: Feb. 14, 2008

(54) Method and Apparatus for the Etching of Microstructures

(76) Inventors: Anthony O'Hara, Livingston (GB); Michael Leavy, Livingston (GB); Graeme Pringle, Livingston (GB); Anthony Mckie, Livingston (GB)

Correspondence Address: SUGHRUE MION, PLLC, 2100 PENNSYLVANIA AVENUE, N.W., SUITE 800, WASHINGTON, DC, 20037, US

(21) Appl. No.: 11/629,943

(22) PCT Filed: Jun. 17, 2005
(86) PCT No.: PCT/GB05/02386

§ 371 Date: Apr. 13, 2007

(30) Foreign Application Priority Data
Jun. 17, 2004 (GB) 0413554.7

(51) Int. Cl. H01L 21/306; B44C 1/22

(52) U.S. Cl. 216/63; 156/345.27; 156/345.29

(57) ABSTRACT

An apparatus and method for providing an etching gas source for etching one or more microstructures located within a process chamber. the apparatus has a gas source supply line attached to a gas source and one or more chambers for containing an etching material. In use, the etching material is transformed into an etching material vapor within one or more of the chamber and the gas supply line provides a supply of carrier gas to the etching material vapor and also supplies the etching material vapor transported by the carrier gas to the process chamber. Advantageously, the apparatus of the invention does not require the incorporation of any expansion chambers or other complicated mechanical features in order to achieve a continuous flow of etching gas.

This invention relates to the field of the manufacturing of microstructures. The microstructures are in the form of micro electromechanical systems (MEMS) that require the removal of a material relative to a substrate or other deposited material. More particularly, this invention relates to an improved method and apparatus for the gas phase etching process involved in the manufacture of these microstructures.

MEMS is a term generally employed by those skilled in the art to describe devices which are fabricated onto a substrate using micro-engineering or lithography based processes. These devices can include mechanical sensors and machines, optical components, bio-engineered devices, RF devices as well as many others.

The employment of an etching process to remove sacrificial layers or regions in a multilayer structure without the removal of an adjacent layer or region is a necessary and common process in the manufacture of MEMS. It is well known to those skilled in the art to employ xenon difluoride (XeF₂) etching techniques within this procedure since XeF₂ isotropically etches silicon spontaneously in the vapour phase without the requirement for external energy sources or ion bombardment. Furthermore, at room temperature the etching rate is high and the selectivity with other materials commonly used in MEMS manufacture (e.g. many metals, dielectrics and polymers) is also known to be extremely high. The above factors make this etching process ideal for the release of MEMS structures when using Silicon as the sacrificial material.

At room temperature and atmospheric pressure XeF₂ is a white crystalline solid, the crystal size being determined by the conditions in which solidification takes place. Sublimation takes place at a partial vapour pressure of ˜4 Torr at 25° C. Partial vapour pressure refers to the pressure exerted by a particular component of a mixture of gas, in this case XeF₂.

However, one draw back to the use of XeF₂ is that it forms HF in the presence of water vapour and so poses a significant safety hazard to users if it is not carefully isolated.

XeF₂ gas etches silicon with the primary reaction as defined by the following expression:
2XeF₂+Si→2Xe+SiF₄ (1)

This reaction is exothermic and so substrate temperature increases are observed during the etching process. As can be seen the rate at which the etching of silicon takes place is proportional to the amount of XeF₂ vapour present i.e. the higher the XeF₂ partial pressure the higher the etch rate.

One of the first reference to this type of etching with respect to MEMS is in E. Hoffman, B. Warneke, E. J. J. Krugglick, J. Weigold and K. S. J. Pister, “3D structures with piezoresistive sensors in standard CMOS”, Proceedings of Micro Electro Mechanical Systems Workshop (MEMS '95), p. 288-293, 1995. Within this apparatus a continuous flow of XeF₂ gas was employed for the etching process.

Following further refinement of this continuous flow process, the apparatus employed was described in detail within F. I. Chang, R. Yeh, G. Lin, P. B. Chu, E. Hoffman, E. J. J. Kruglick and K. S. J. Pister, “Gas Phase Silicon Micromachining With Xenon Difluoride In Microelectronic Structures And Microelectromechanical Devices For Optical Processing And Multimedia Applications”, Proc. SPIE. Vol. 2641, p. 117-128, 1995 and U.S. Pat. No. 5,726,480 in the name of The Regents of the University of California, see FIG. 1.

The continuous etching apparatus 1 of FIG. 1 can be seen to comprise an etching chamber 2 connected by a first valve 3 to a source chamber 4 that contains the XeF₂ crystals. Nitrogen (N₂) purging is also provided to the etching chamber 2 through a second valve 5. Once the etching chamber 2, with the sample devices inside, has been pumped down to a moderate vacuum by a vacuum pump 6, the first valve 3 is opened and small amounts of the XeF₂ crystals vaporise in the low pressure and so XeF₂ gas enters the etching chamber 2. Under these conditions, typical etch rates of 1-3 microns per minute are observed, although as is appreciated by those skilled in the art, the exact etching rate is dependent on the size and density of the features being etched.

A major disadvantage with this continuous etching apparatus 1 is the lack of control it provides for the etching process. The first valve 3 moves between an open and closed position so the flow of the etching gas is correspondingly either on or off. A further disadvantage of this system resides in the fact that it depends directly on a pressure differential between the source chamber 4 and the etching chamber 2 so as to cause the required vaporisation of the XeF₂ crystals. Therefore, any increase in pressure within the etching chamber 2 or decrease in pressure within the source chamber 4 results in a reduced efficiency in the operation of the apparatus 1. The etching process is therefore directly dependent on the quantity, age and history of XeF₂ crystals within the source chamber 4.

It is also recognised by those skilled in the art that since the reaction of equation (1) is exothermic, cooling of the sample is desirable to prevent the temperature of the sample increase causing an issue such as thermal shock which can damage the sample, this is commonly achieved by adding an inert gas. Typically, this can be achieved by opening the second valve 5 so as to allow nitrogen gas into the etching chamber 2 since this inert gas acts as coolant. However, it should be noted that when the nitrogen gas is introduced into the etching chamber 2 the efficiency of the etching process is decreased. This occurs because of the resulting increase in the pressure within the etching chamber that then causes a reduction in the flow of XeF₂ into the etching chamber 2.

Historically, continuous etching systems have been regarded as wasteful and expensive since the constant flow of XeF₂ gas increased the quantity of the relatively expensive XeF₂ crystals used.

In order to attempt to circumvent one or more of the above disadvantages, so-called pulsed etching apparatus have been developed. The first of these was described in P. B. Chu, J. T. Chen, R. Yeh,. G. Lin, J. C. P Huang, B. A. Wameke, and K. S. J. Pister, “Controlled Pulse-Etching with Xenon Difluoride”, Transducers '97, Chicago Ill., p. 1-4, June 1997. This pulsed etching system 7 is presented schematically in FIG. 2. The system 7 can be seen to employ an intermediate chamber, referred to as an expansion chamber 8, to pre-measure a quantity of XeF₂ gas and to mix this gas with other gases, such as a nitrogen coolant gas employed to enhance the etching process. The contents in the expansion chamber 8 are then discharged into the etching chamber 2 so as to perform the required etching of the silicon. After the XeF₂ gas has been sufficiently reacted, the etching chamber 2, and typically the expansion chamber 8 as well, are evacuated through the use of a roughing or vacuum pump 6. This process is repeated until the desired degree of etching of the silicon has occurred.

The pulsed etching system 7 described above still exhibits certain inherent disadvantages. In the first instance it still does not truly control the XeF₂ gas flow. The pressure in the etching chamber 2 is determined by the charge pressure in the expansion chamber 8, and so by the volume ratio of the etching 2 and expansion chambers 8. When the expansion chamber 8 is attached to the etching chamber 2 the pressure inevitably drops. The new partial pressure is dependent on the ratio of the volumes of the expansion chamber 8 to the etching chamber 2. For example, if the etching chamber 2 is the same size as the expansion chamber 8 then when they are connected the partial pressure of the XeF₂ is halved. As a direct result the etching rate is also halved. Thus, in such systems the etching rate is dependent on the ratio of expansion chamber 8 to etching chamber 2. Therefore, the etching pressure is not controlled directly and in practice is usually only about half the usable pressure as the expansion chamber 8 and the etching chamber 2 are typically of a similar volume.

A second significant drawback of this system 7 resides in the cyclic operating nature of the system. In particular, since the expansion chamber 8 requires time to fill before the etching begins, it is open to the etching chamber 2 during the etching process, and is typically evacuated during the evacuation step of the cycle, it forms a rate-limiting step in the etching process. This limitation arises primarily from the time it takes to refill the expansion chamber 8 with XeF₂ gas after the evacuation step of the previous cycle. The waiting time can often be a significant period of the etching cycle thus resulting in the total process time, or the time the device spends in the etching chamber 2, being approximately double that of the actual etching time.

A further draw back of this system results from the fact that when the expansion chamber 8 and the etching chamber 2 are connected they are also isolated from any external influence. Thus the partial pressure of the XeF₂ vapour in the chambers at the instant they are connected is maximised. However, as the etching proceeds the amount of XeF₂ vapour in the chamber drops and as this happens the etching rate also drops. In trying to maximise the utilisation of XeF₂ for etching purposes extremely long etching times result. Furthermore, in a practical etching system there will also always be XeF₂ vapour pumped away.

An improved pulsed etching system is described in US Patent Application No. US 2002/0033229 in the name Lebouitz et al. This application teaches of a system that comprises variable volume expansion chambers, fixed volume expansion chambers or combinations thereof, in fluid communication with an etching chamber and a source of etching gas, such as XeF₂ gas. The incorporation of multiple expansion chambers alleviates the down time experienced in refilling the expansion chamber of the Chu et al. system 7. Furthermore, the fact that the expansion chambers are collapsible allows for some control of the etching pressure, however this pressure control is still only of a secondary nature.

A further alternative pulsed etching system is described in US Patent Application No. US 2002/0195433 in the name Reflectivity Inc. This application teaches of a pulsed etching system that again comprises variable volume expansion chambers. A significant addition to this particular system is the inclusion of a re-circulating pumping system. Thus, once the etching chamber is charged the pump is used to recirculate the gas in an attempt to improve etching rate and uniformity of the process.

A significant drawback of both the Lebouitz et al system and the Reflectivity Inc. system is the increased engineering required to produce the device and the increased capital involved with not only the increased engineering but the additional components required.

### SUMMARY OF INVENTION

According to a first aspect of the present invention there is provided an apparatus for providing an etching gas source for etching one or more microstructures located within a process chamber, the apparatus comprising a gas source supply line connectable to a gas source and one or more chambers adapted to contain an etching material wherein the etching material is transformed into an etching material vapour within the one or more chambers, and the gas supply line provides a means for supplying a carrier gas from the gas source to the etching material vapour and thereafter for supplying the etching material vapour transported by the carrier gas to the process chamber.

Preferably the etching material is solid when under standard state conditions. Alternatively, the etching material is liquid when under standard state conditions. Most preferably the carrier gas also functions as a coolant for the etching of the one or more microstructures within the process chamber.

Optionally the one or more chambers comprise a temperature control means so as to provide a means for controlling the temperature within the chamber.

Optionally the temperature control means is applied to the entire apparatus.

Optionally the temperature control means comprises at least one heating element.

Optionally the one or more chambers comprise a meshed frame suitable for supporting the etching material and which defines a sub-chamber area located below the etching material.

Preferably the one or more chambers comprises a first conduit that couples the one or more chambers to the gas supply line. In this embodiment the etching material vapour is drawn into the gas supply line, via the first conduit, absorbed by the carrier gas and thereafter supplied to the process chamber, as required.

Optionally the one or more chambers further comprise a second conduit that couples the one or more chambers to the gas supply line. In this alternative embodiment the carrier gas is supplied directly into the one or more chambers via the first conduit. The carrier gas then transports the etching material vapour before being returned to the gas supply line via the second conduit.

Preferably one end of the first conduit is located within the one or more chambers so that the carrier gas is supplied directly above a first surface of the etching material. Optionally the end of the first conduit is located within the sub-chamber.

Optionally one end of the second conduit is located within the one or more chambers so that the carrier gas is supplied directly below the first surface of the etching material. Optionally the end of the second conduit is located within the sub-chamber.

Optionally the apparatus further comprises a conduit support tube that provides a channel for locating the first or second conduit within the etching gas source.

Preferably the apparatus further comprises a plurality of artificial voids that provide a means for increasing the surface area between the carrier gas and the etching material.

Preferably the apparatus comprises a plurality of packing material adapted to form said artificial voids.

Preferably the packing material comprises a material of good thermal conductivity. Optionally the packing material comprises polytetrafluoroethylene. In a further alternative, the packing material comprises stainless steel or aluminium.

In yet a further alternative, the apparatus comprises a preformed insert adapted to form said artificial voids.

Optionally the etching gas source further comprises one or more mechanical vibrators that provides a means for vibrating the one or more chambers. In this embodiment the first and second conduits preferably comprise flexible pipes.

Optionally the one or more chambers comprises one or more substantially tangential entrance conduits each of which are coupled to the first conduit so as to provide a means for allowing the carrier gas to physically stir the etching material.

Optionally the etching gas source comprises two or more chambers connected together in series. In this embodiment it is ensured that the etching material saturates the carrier gas before being supplied to the process chamber.

Most preferably the etching material comprises a noble gas fluoride. Preferably the noble gas fluoride is selected from a group comprising krypton difluoride and the xenon fluorides. The xenon fluorides are a group comprising xenon difluoride, xenon tetrafluoride and xenon hexafluoride.

Alternatively the etching material comprises a halogen fluoride. Preferably the halogen fluoride is a member selected from a group comprising bromine trifluoride, chlorine trifluoride and iodine pentafluoride.

Preferably the carrier gas comprises an inert gas. Most preferably the inert gas is helium.

Alternatively the carrier gas is nitrogen.

Preferably the supply of the carrier gas to the chamber is controlled by one or more mass flow control devices.

Additionally the supply of the carrier gas to the chamber is further controlled by one or more valves.

According to a second aspect of the present invention there is provided a gas phase etching apparatus comprising a process chamber suitable for locating one or more microstructures and an etching gas source in accordance with the first aspect of the present invention.

Preferably the etching gas source is located within an input line to the process chamber.

Preferably the gas phase etching apparatus further comprises a vacuum pump located within an output line from the process chamber that provides a means for creating and maintaining a vacuum within the process chamber.

Preferably a pressure gauge is coupled to the process chamber so as to provide a means for monitoring the pressure within the process chamber.

Preferably the gas phase etching apparatus further comprises a gas vent located within the input line to the process chamber that provides a means for venting the process chamber.

Optionally the gas phase etching apparatus further comprises one or more additional fluid supply lines connected to the input line so as to provide a means for supplying additional processing fluids to the process chamber, e.g. water.

Preferably the one or more additional fluid supply lines are connected to the vacuum pump.

According to a third aspect of the present invention there is provide a method of etching one or more microstructures located within a process chamber, the method comprising the steps of:
1) transforming an etching material from a first state into an etching material vapour;
2) employing a carrier gas to transport the etching material vapour and thereafter supply the etching material vapour to the process chamber.

Optionally the method is repeated to ensure that the carrier gas is saturated with the etching material vapour.

Most preferably the transformation of the etching material comprises the sublimation of the etching material from a first state that is solid.

Alternatively the transformation of the etching material comprises the vaporisation of the etching material from a first state that is liquid.

Most preferably the carrier gas also functions as a coolant for the etching of the one or more microstructures within the process chamber.

Preferably the efficiency of the pick-up of the etching material vapour by the carrier gas is increased by the addition of artificial mechanical voids to the etching material.

Preferably the addition of packing material to the etching material creates said artificial mechanical voids.

Preferably the artificial mechanical voids create multiple pathways that the carrier gas may propagate through such that the area of contact between the carrier gas and the etching material is increased.

Preferably the efficiency of the pick-up of the etching material vapour by the carrier gas is increased by agitating the etching material.

Preferably the efficiency of the method of etching is increased by heating the etching material so as to maintain the material at a constant predetermined temperature.

Preferably the partial pressure of the etching material vapour within the process chamber is maintained below the vapour pressure of the etching material.

Optionally the partial pressure of the etching material vapour is increased by increasing the temperature of the etching material.

Optionally the rate at which the etching occurs is increased by increasing the partial pressure of the etching material vapour within the process chamber.

Preferably the method comprises the additional step of selecting a partial pressure of etching material vapour in the process chamber in response to the size of the one or more microstructures to be etched.

Optionally the rate at which the etching material vapour is supplied to the process chamber is selected in response to a desired etch rate and a rate of removal of etching material vapour from the process chamber.

Optionally the method comprises the additional step of providing a breakthrough step in which a native oxide layer is etched.

Preferably the breakthrough step comprises adding a fluid selected to react with the etching material vapour in the process chamber, the product of which etches the native oxide layer.

Preferably the breakthrough step comprises decomposing the XeF₂ using an energy source such as plasma, ion beam or UV light. The fluorine gas produced then etches the oxide layer.

Optionally the method further comprises the additional steps of:
1. preventing the supply of carrier gas;
2. employing a vacuum pump to pump the etching material to the process chamber; and
3. measuring the pressure in the process chamber;

wherein measuring the pressure in the process chamber provides a means of determining the amount of etch material in the source chamber.

Optionally the amount of etch material in the source chamber is determined by determining the sublimation rate of the etch material.

Optionally the method further comprises the steps of:
1. preventing gas flow out of the process chamber;
2. monitoring the rise in pressure in the process chamber; and
3. determining the rate of rise in pressure in the process chamber;

wherein determining the rate of rise of pressure provides a means of monitoring the consumption of etch material in the source chamber.

Optionally the method comprises the additional steps of:
1. measuring the carrier gas flow to the source chamber;
2. measuring the total mass flow of etching material vapour and carrier gas leaving the source chamber; and
3. determining the etch material vapour flow from the total mass flow and the carrier gas flow;

wherein determining the etch material vapour flow provides a means of feedback to control the carrier gas flow in order to provide a controlled supply of etch material vapour to the process chamber.

### BRIEF DESCRIPTION OF DRAWINGS

Aspects and advantages of the present invention will become apparent upon reading the following detailed description and upon reference to the following drawings in which:

FIG. 1 presents a schematic representation of the apparatus employed within the prior art for carrying out a continuous XeF₂ etching process;

FIG. 2 presents a schematic representation of the apparatus employed within the prior art for carrying out a pulsed XeF₂ etching process;

FIG. 3 presents a schematic representation of apparatus employed for gas phase etching of a micro electromechanical microstructure in accordance with an aspect of the present invention;

FIG. 4 presents a schematic representation of an etching gas supply system employed within the apparatus of FIG. 3;

FIG. 5 presents a schematic representation of a process chamber employed within the apparatus of FIG. 3;

FIG. 6 illustrates schematically the dependence of the etch rate on the partial pressure of XeF₂, and subsequent dependencies on other parts of the system;

FIG. 7 presents a schematic representation of a breakthrough step employed by the gas phase etching apparatus of FIG. 3;

FIG. 8 presents a schematic representation of an alternative embodiment of the etching gas supply system of FIG. 3 that incorporates artificial mechanical voids within a crystal structure;

FIG. 9 presents a schematic representation of an alternative embodiment of the etching gas supply system of FIG. 3 that incorporates a mechanical vibrator;

FIG. 10 presents a schematic representation of a yet further alternative embodiment of the etching gas supply system of FIG. 3 that incorporates a carrier gas mixing system;

FIG. 11 presents a schematic representation of a yet further alternative embodiment of the etching gas supply system of FIG. 3 that incorporates an entrance conduit support, thermally conductive mesh, and thermally conductive packing material;

FIG. 12 presents a schematic representation of an overflow etching gas supply system in accordance with an alternative embodiment of the present invention;

FIG. 13 presents a schematic representation of a double etching gas supply system in accordance with an alternative embodiment of the present invention;

FIG. 14 presents a schematic representation of a pressurised carrier gas source;

FIG. 15 presents a graph illustrative of the rise of XeF₂ pressure within the process chamber when gas flow out of the process chamber is stopped;

FIG. 16 presents a schematic representation of a mass flow meter being used to monitor carrier gas flow; and

FIG. 17 presents a schematic representation of an additional gas line being adopted for the purposes of carrier gas compensation.

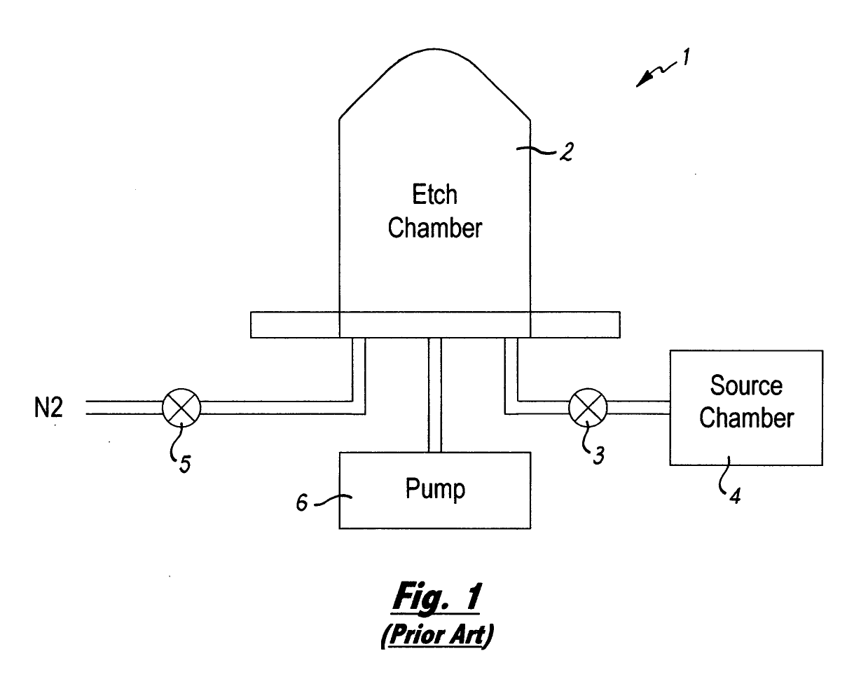

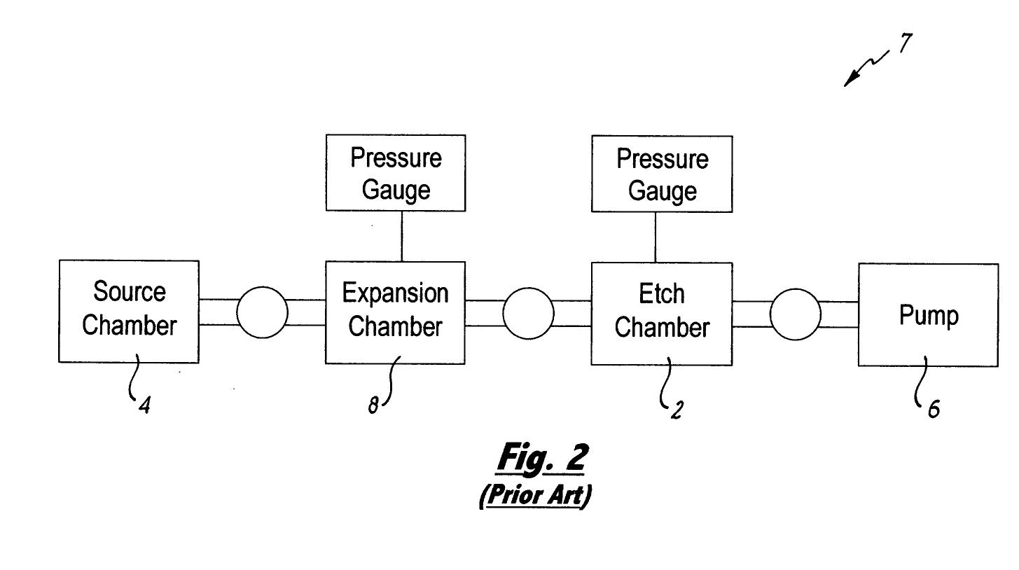

### DETAILED DESCRIPTION

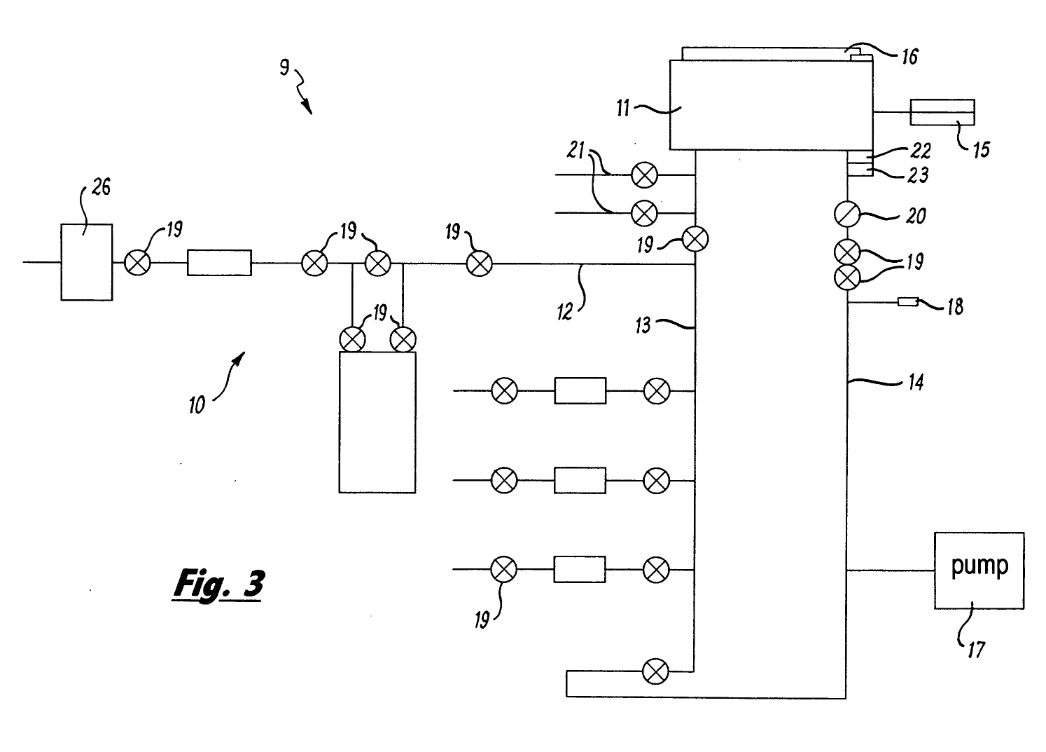

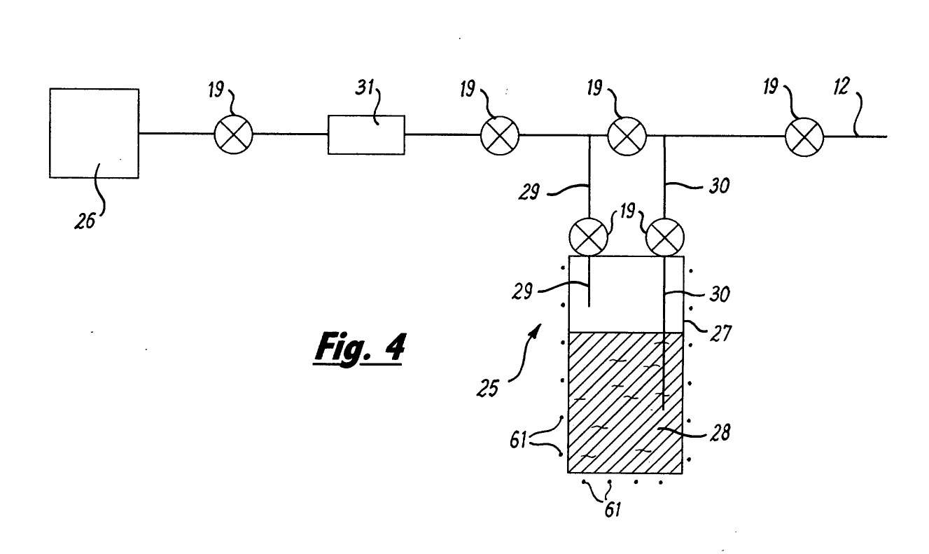

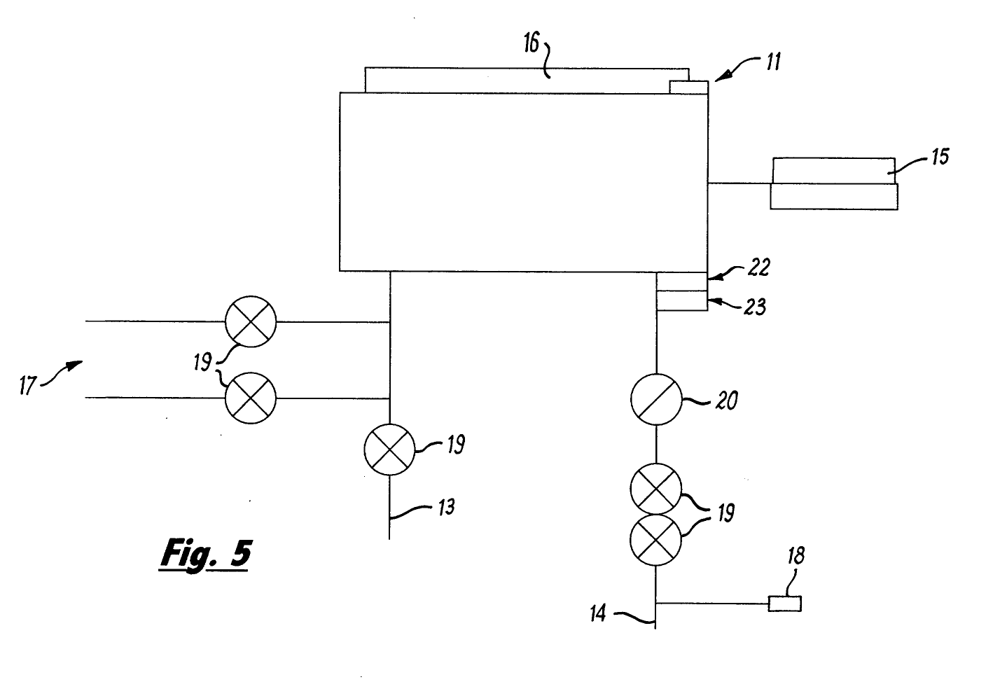

Referring initially to FIG. 3 a schematic representation of a gas phase etching apparatus 9, employed for the manufacture of micro electromechanical microstructures (MEMS) is presented in accordance with an aspect of the present invention. The gas phase etching apparatus 9 can be seen to comprise an etching gas source, depicted generally at 10 and shown in further detail within FIG. 4, and a process chamber, depicted generally at 11 and shown in further detail within FIG. 5.

The etching gas source 10 is employed to provide the required XeF₂ etching gas to the process chamber 11 via a first gas supply line 12 and a process chamber input line 13. Also coupled to the process chamber 11 is a pumping line 14 and a first pressure gauge 15 that provides a means for determining the pressure within the process chamber 11. The process chamber 11 can be seen to further comprise a lid 16 that provides a means of access to the chamber 11 so as to allow for the loading and unloading of the MEMS devices, as and when required.

Samples, specifically wafers, can be located automatically through a side port when the chamber is connected to an automatic wafer handling system.

Located within the pumping line 14 is a vacuum pump 17, a second pressure gauge 18, two valves 19 and an automatic pressure control switch 20. The combination of these elements provide a means for producing and maintaining a vacuum within the process chamber 11, and then to control a chamber pressure with controlled set gas flows at a sufficient level to allow for the etching process to take place, as is known to those skilled in the art.

From FIG. 3 it can be seen that located within the process chamber input line 13 is a vent line 21 that provides a means for venting the process chamber 11. In particular, the vent line 21 is employed to allow for a flow of gas into the process chamber 11 when the pump 17 isolated from the system so as to raise the process chamber 11 pressure to atmosphere thus allowing the lid 16 to be opened. In this embodiment the gas supplied is nitrogen although air may also be used as an alternative.

An atmospheric switch 22 and an over pressure switch 23 are also located within the pumping line 14. The function of the atmospheric switch 22 is to provide a means for indicating when the process chamber 11 is at atmospheric pressure and so the chamber lid 16 can be opened. The over pressure switch 23 is linked to an apparatus control system (not shown) and provides a safety override for the process chamber 11.

From FIG. 3 it can also be seen that located within the process chamber input line 13 are three (can be any number) additional gas supply lines 24 that can be employed to supply further process gases to the process chamber 11, as and when required. The process chamber input line 13 is connected to the pumping line 14 so as to provide a means for pumping out these additional gas supply lines 24.

FIG. 4 presents further detail of the etching gas source 10. The etching gas source 10 can be seen to comprises an etching gas supply system 25 and a carrier gas source 26 both of which are located within the first gas supply line 12. The etching gas supply system 25 comprises a sealed chamber 27 that houses XeF₂ crystals 28, an entrance conduit 29 and an exit conduit 30. The entrance conduit 29 is located above the surface of the XeF₂ crystals 28 and functions to provide a means for delivering a carrier gas, namely helium gas (He₂), from the carrier gas source 26 directly to the XeF₂ crystals 28. The exit conduit 30 penetrates below the level of the XeF₂ crystals 28 and is employed as a means to deliver XeF₂ vapour, carried by the helium carrier gas, to the process chamber 11. Temperature control within the sealed chamber 27 is achieved by the incorporation of heating elements 61 located at the external surface of the chamber. In an alternative embodiment the heating elements 61 may extend underneath the chamber 27, and in yet another embodiment the heating elements 61 may provide heat to all of the components of the apparatus. Volume flow control of the carrier gas within the system is regulated by the combination of valves 19 and a Mass Flow Control (MFC) device 31 located within the first gas supply line 12.

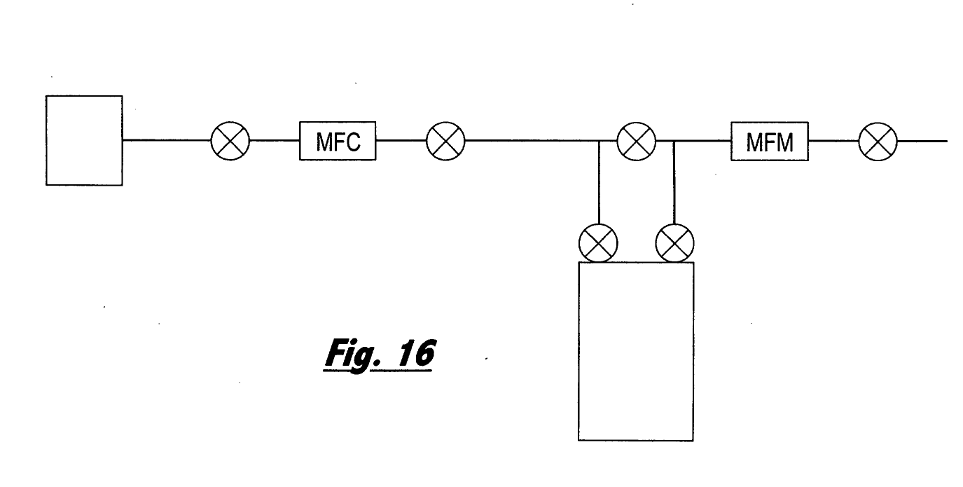

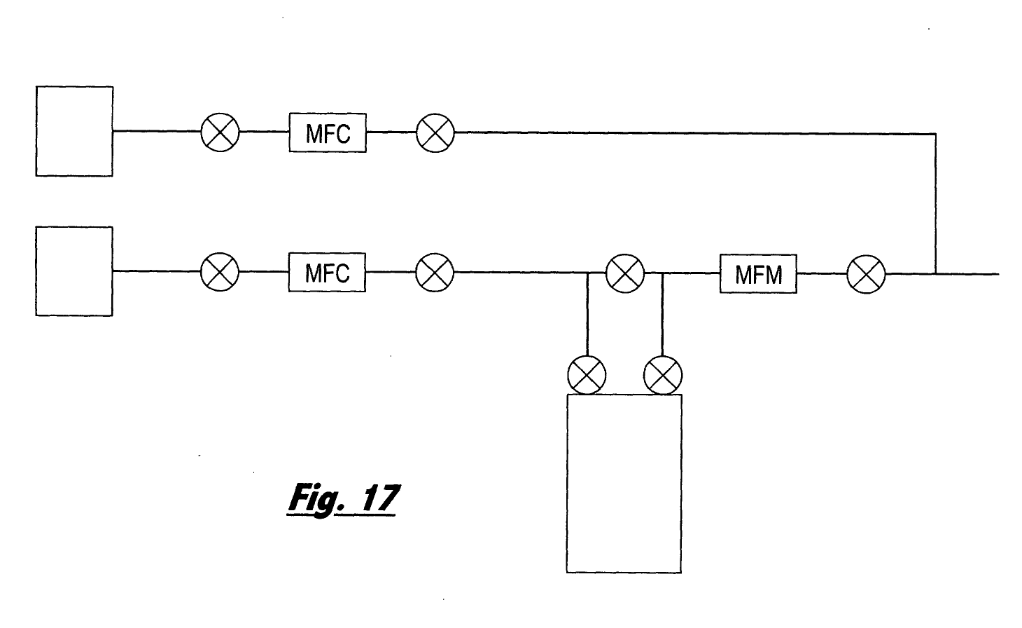

A MFM on the supply line 12 monitors the gas flow in the line and by comparison with the carrier gas MFC supply the XeF₂ flow can be determined. (See FIG. 16 and accompanying discussion below).

The principle of operation of the gas phase etching apparatus 9 is as follows. When the partial pressure of the XeF₂ vapour within the sealed chamber 27 is less than ˜4 Torr then sublimation of the XeF₂ crystals 28 occurs and XeF₂ vapour is formed within the sealed chamber 27. The helium gas within the carrier gas source 26 is maintained at a pressure of ˜30 psi such that when an electrical signal is supplied to the MFC device 31 a controlled supply of helium gas to the sealed chamber 27 is achieved. The helium gas then acts to pick up the XeF₂ vapour that has sublimated from the XeF₂ crystals 28 and carry it, via the exit conduit 30, to the process chamber 11.

Etching of one or more MEMS devices located within the process chamber 11 can then take place in a similar fashion to that known to those skilled in the art. It should be noted that the helium carrier gas also provides a secondary function in that it acts as a coolant for the etching process so increasing the efficiency of this process.

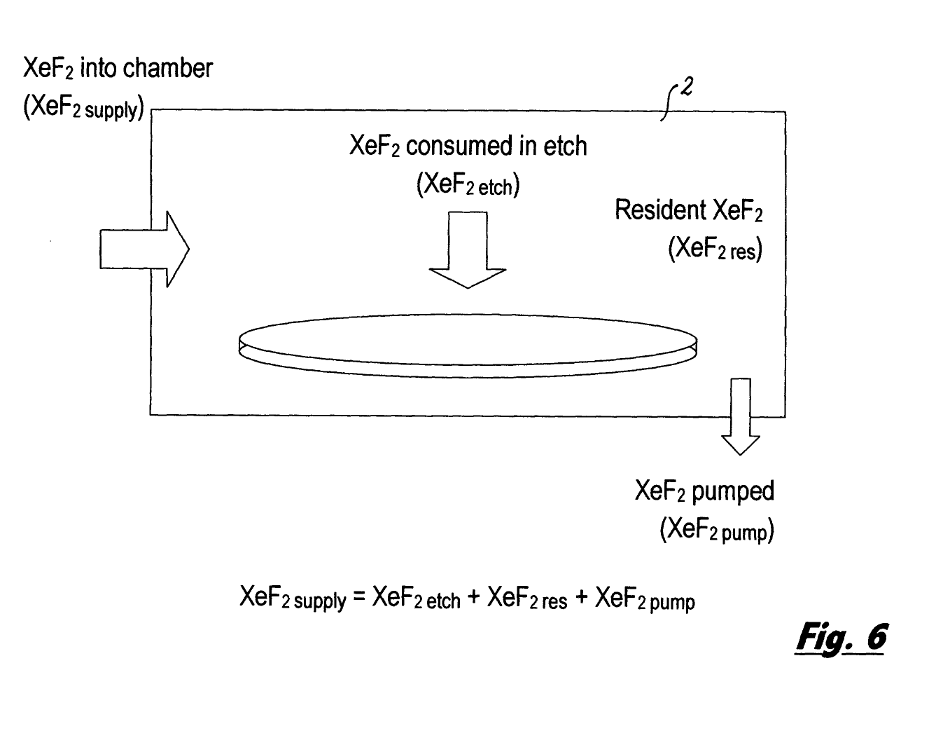

In practice, it is found that the etch rate is dependent on the partial pressure of the XeF₂ in the etching chamber 2. The XeF₂ partial pressure in turn is dependent on the amount of XeF₂ being supplied to the etching chamber 2, the XeF₂ being consumed by the etching process and the amount of XeF₂, if any, being pumped away, as presented schematically in FIG. 6 and expressed in Equation (2) below:
XeF_{2 supply}=XeF_{2 etch}+XeF_{2 pump}+XeF_{2 res} (2)

Thus, the amount of XeF₂ supplied to the etching chamber 2 (XeF_{2 supply}) is in equilibrium with the amount of XeF₂ being consumed by the etching process (XeF_{2 etch}), the XeF₂ being pumped from the chamber 2 (XeF_{2 pump}) and the amount of XeF₂ resident in the chamber 2 (XeF_{2 res}).

It is the amount of XeF₂ resident in the chamber 2 that ultimately determines the partial pressure of the XeF₂. Thus, to achieve as high an etching rate as possible, the partial pressure in the etching chamber 2 needs to be as high as possible. However, there is an upper limit in that the partial pressure must not exceed the vapour pressure or else the XeF₂ vapour will recrystalise.

Typically, the vapour pressure of XeF₂ at room temperature is ˜4 T and is known to be temperature dependent such that increasing the temperature increases the vapour pressure. Therefore, it is found that by employing heating elements 50 to heat the etching chamber 2, the gas supply line 12, the etching chamber input line 13 and the etch chamber 2 acts to increase the vapour pressure, so allowing a higher XeF₂ partial pressure to be obtained.

The partial pressure must not rise above the vapour pressure for the temperature of the system or re-crystallisation will occur. In many systems it is common to have the source at a given temperature and then have the subsequent components through to and including the processing chamber at a higher temperature to ensure no re-crystallisation of the XeF₂. This set-up will lead to a more complex apparatus. The amount of components requiring to be heated can be reduced. With very good system control, heating of the process chamber may not be required.

To further illustrate this point consider the complete apparatus 9 as a single system all at the same temperature, e.g. room temperature ˜25° C., the vapour pressure of the XeF₂ is thus ˜4 Torr. The rate of sublimation is dependent on the temperature, the crystal surface area and the partial pressure of the XeF₂. At a set temperature the etching gas source 10 is capable of supplying a set amount of XeF₂ vapour into the etching chamber 2. The pumping speed can then be set to control the amount of XeF₂ resident in the chamber 2 thus, the remaining mechanism for removing the XeF₂ vapour from the chamber 2 is the etch itself. The amount of XeF₂ being consumed in the etch process is primarily dependent on the amount of exposed silicon, e.g. for the same photolithography pattern a 150 mm diameter wafer will consume XeF₂ at a faster rate than if it were a 100 mm diameter wafer. This means that if there is a large amount of exposed silicon removing XeF₂ vapour in the etch process the partial pressure in the etching chamber 2 will be reduced to a level much lower than the vapour pressure. Therefore, in practice the supply of XeF₂ vapour can be increased, as long as the partial pressure remains below the vapour pressure, so increasing the overall etch rate. Thus, by increasing the temperature of the etching gas source 10 the vapour pressure in the etching gas source 10 increases and therefore the XeF₂ crystals generate more XeF₂ vapour. Supplying more XeF₂ vapour to the etching chamber 2 increases the partial pressure and leads to higher etch rates.

The above described method relies on very good control of the etch process. As the etch proceeds the system is stable and balanced with the XeF₂ supply being matched by the etch rate and the pumping rate. At the end of the etch, whether caused by running out of silicon in a sacrificial mode or ending the etch in a timed mode the etch dynamics change. As the XeF₂ being removed due to etching silicon reduces, or is removed completely, the supply of XeF₂ to the chamber or the XeF₂ vapour removed by pumping must be controlled to ensure that the partial pressure in the etch chamber does not rise above the vapour pressure. In the case of the sacrificial etch an endpoint/process monitor in a feedback loop is required to determine when the etch dynamics are changing and a system response is required.

It will be appreciated by those skilled in the art that the etch rate may be further increased, in a similar manner, by also increasing the temperature of the etching chamber 2, thereby allowing a higher partial pressure to be employed in the process chamber.

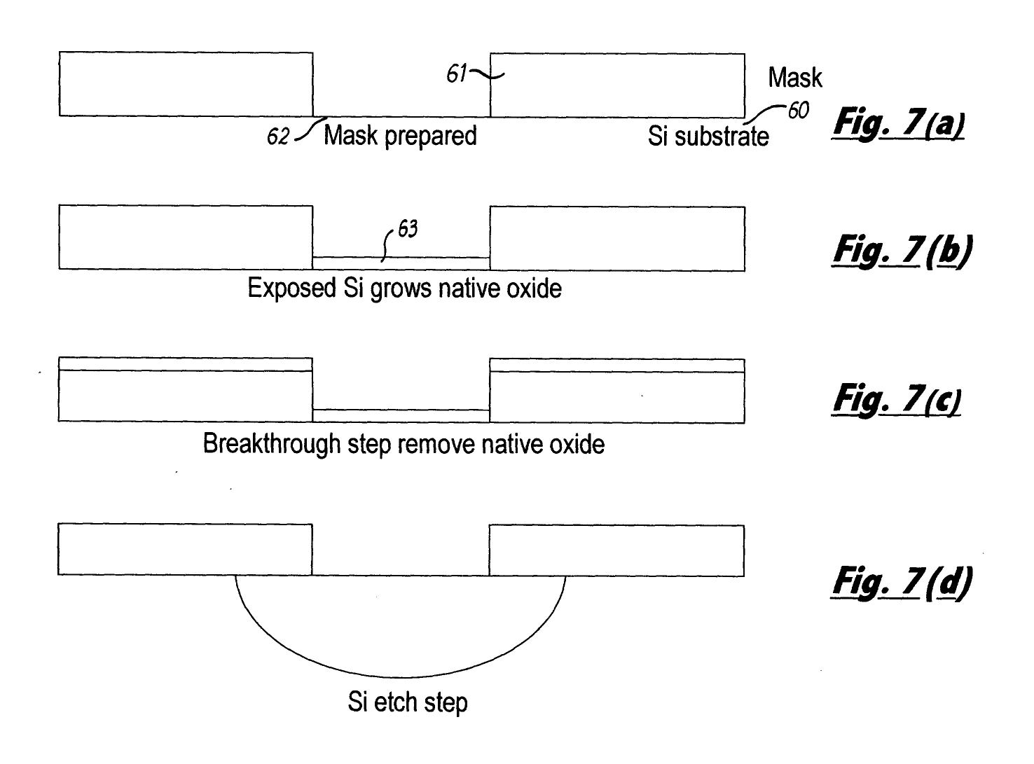

As is known to those skilled in the art there normally exists a number of processing steps carried out on a MEMS structure before etching takes place. These steps are illustrated schematically in FIG. 7 and include the preparation of a sample 60 and the manufacture of a mask 61, see FIG. 7(a). The exposed silicon 62 to be etched, if left in a suitable environment, will grow a thin oxide layer 63, referred to as native oxide, see FIG. 7(b). The thickness of this layer is dependent on the time left exposed.

In highly selective silicon etch processes, e.g. XeF₂ etching, the time taken to etch the native oxide 63 can be considerable. Also, as the thickness of this layer is dependent on the time the silicon has been exposed the thickness of the native oxide 63 can be variable. To remove the native oxide 63 within the etching apparatus 9 a separate processing breakthrough step can be introduced. This step is used only to remove the native oxide 63 and since it is optimised for this purpose leads to faster and more controlled processing of the MEMS.

The breakthrough step can be achieved by using a SiO₂ etch process, commonly a plasma etch using fluorine chemistry. However, it is possible to use the XeF₂ gas as the source of the fluorine etch. The XeF₂ can be disassociated by the application of energy from various sources, e.g. plasma, ion bombardment but preferably UV light. The disassociated fluorine will then etch the oxide layer.

Alternatively, the breakthrough step is achieved, when using XeF₂ as the silicon etching gas, by initially adding a small controlled amount of water vapour to the process chamber 11 during the breakthrough step. Since XeF₂ reacts with the water vapour to produce hydrofluoric acid (HF), the resultant HF etches the native oxide 63.

When an oxide is employed as the mask 61 this will also be etched by the HF. However, the duration of the breakthrough step is relatively short and so only a small amount of mask material will normally be consumed, see FIG. 7(c). With the breakthrough step complete the water vapour and any residual HF vapour is removed and the silicon etch process step begins as represented in FIG. 7(b). Employing the breakthrough step leads to better process control and a more repeatable process from sample to sample.

The efficiency of the pick up process of the XeF₂ vapour by the Helium carrier gas is found to depend on a number of factors including:
The volume of XeF₂ crystals 28 present in the sealed chamber 27;
The XeF₂ vapour pressure, that is known to be temperature dependent;
The flow rate of the helium carrier gas;
The pressure within the sealed chamber 27;
The packing density and crystal size of the XeF₂ crystals 28; and
The geometry of the sealed chamber 27.

An unfavourable process found to take place within the etching gas supply system 25 employed within the present invention is the tendency of the helium carrier gas to create preferential channels through the densely packed XeF₂ crystals 28. As the helium gas flows through these channels there is less vapour pick up as there is a smaller area of contact between the carrier gas and the XeF₂ crystals 28.

As the channels within the XeF₂ crystals 28 continue to expand the efficiency of the pick up of the carrier gas deteriorates until the XeF₂ crystal structure becomes unstable. The XeF₂ crystal structure will then collapses upon itself so that the carrier gas pick up process is of a different form. The described channel formation process therefore results in a non uniform pick up and depletion of the XeF₂ crystals 28.

Various alternative embodiments of the etching gas supply system shall now be described which are designed to reduce the problematic effect of channel formation within the XeF₂ crystal 28.

In a first alternative embodiment the position of the lower ends of the entrance conduit 29 and the exit conduit 30 can be varied. For example both lower ends may be located above or below the top surface of the XeF₂ crystals 28. Alternatively, only the lower end of the exit conduit 30 is located below the top surface of the XeF₂ crystal 28.

FIG. 8 illustrates an alternative etching gas supply system 32 that comprises packing material 33 in the form of small cylinders made from polytetrafluoroethylene (PTFE), that have been added periodically throughout the XeF₂ crystals 28. The addition of the packing material 33 acts to increase the number of paths available to the helium carrier gas to propagate through the XeF₂ crystals 28 and so increases the area of contact between these elements. This results in a more even consumption of the XeF₂ crystals 28 due to a reduction in the channel formation process described above. Therefore, the etching gas supply system 32 exhibits a more uniform flow of the XeF₂ gas to the process chamber 11.

Although the packing material 33 has been described as comprising PTFE, any material that does not react with XeF₂, in crystal or vapour form, or the carrier gas may also be employed e.g. glass, or stainless steel or aluminium due to their better thermal conduction properties. Furthermore, the packing material 33 may comprise alternative geometrical shapes such as spring structures or spheres.

A further advantage of the packing material 33 is achieved if this material also exhibits good thermal conductivity properties. This is because during periods when the etching gas source 10 is idle (i.e. between wafer runs) the XeF₂ crystals 28 and the vapour reach an equilibrium with the partial pressure of XeF₂ in the etching gas source 10 equal to the vapour pressure for that particular temperature. Sublimation and re-crystallisation continues to take place. When the carrier gas starts to flow again in the apparatus 1 the etching gas source 10 is activated so as to again supply the XeF₂ vapour and so more sublimation is required. Energy is needed to generate the gas and in the process of supplying this energy the XeF₂ crystals 28 cool down. This in turn slows the sublimation resulting in lower XeF₂ gas flow and a lower etch rate. As the system continues to operate an effective lower temperature equilibrium state is reached and a stable, but reduced, XeF₂ gas flow is achieved. However the employment of a thermally conducting packing material 33 results in heat being easily supplied from the walls of the etching gas source 10 and the heating elements 50, therefore reducing the detrimental cooling effect on the XeF₂ crystals 28.

Thus, in a highly controlled system as described above, an appropriate amount of additional heat can be added to compensate for the heat being lost through the sublimation process.

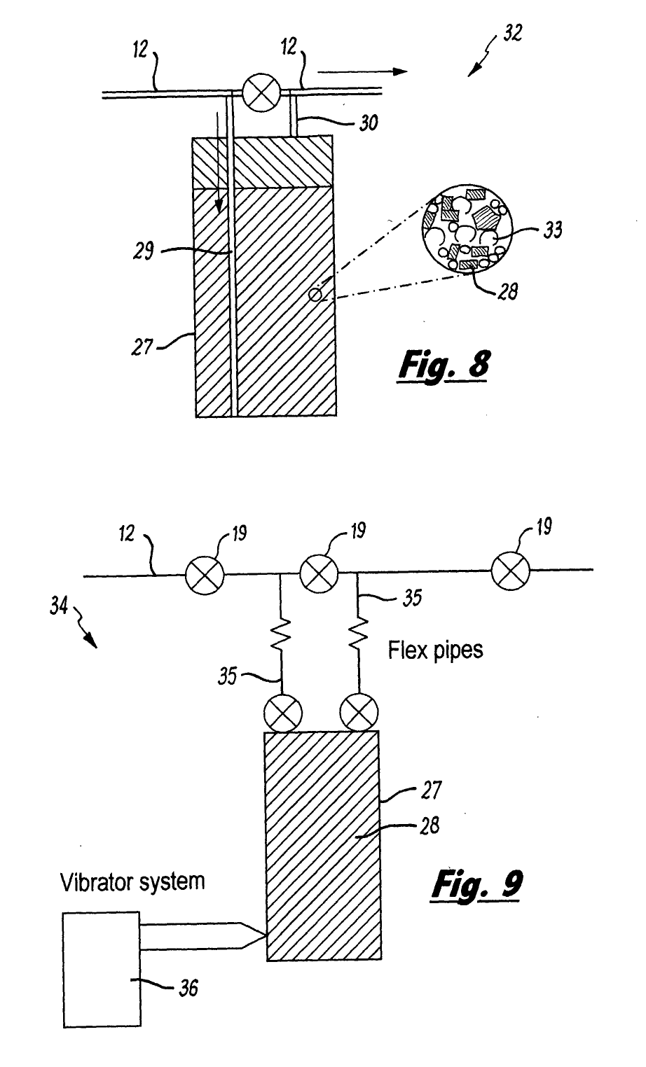

FIG. 9 presents alternative apparatus for overcoming the detrimental effect of channelling within the XeF₂ crystals 28. Within this embodiment the etching gas supply system 34 comprises a sealed chamber 27 that is connected to the first gas supply line 12 via two flex pipes 35. Located at the lower end of the sealed chamber 27 is a mechanical vibrator 36 which acts in conjunction with the flex pipes 35 to mechanically vibrate the sealed chamber 27. As a direct result of this vibrational motion, the XeF₂ crystals 28 contained within the sealed chamber 27 are continuously moved so as to remove the opportunity for gas carrier channels to form within crystal structure. The mechanical vibrator 36 thus results in reduced channelling and so provides a smoother pick up, and even consumption, of the XeF₂ crystals 28.

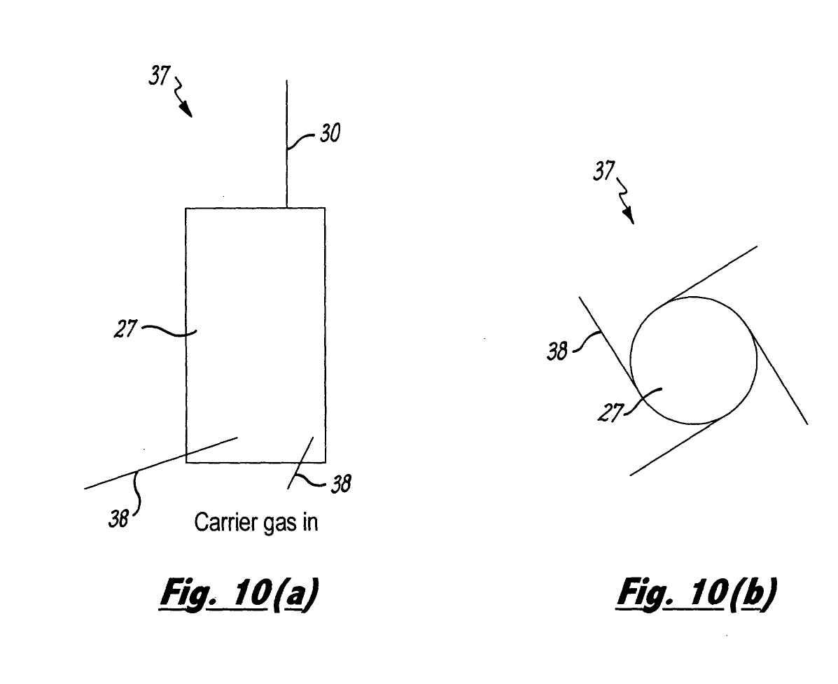

FIGS. 10(a) and (b) present a schematic front view and plan view of an etching gas supply system 37 in accordance with a further alternative embodiment of the present invention. In this embodiment the helium carrier gas is introduced to the lower region of the sealed chamber 27 via four substantially tangential entrance conduits 38. A single longitudinal exit conduit 30 is present in order to provide a means for relaying the XeF₂ gas and the helium carrier gas to the process chamber 11, as appropriate.

The introduction of the helium carrier gas via four separate entrance conduits 38 results in a vortex being created within the sealed chamber 27. This vortex acts to stir the XeF₂ crystals 28 and so again prevents channels being produced by the carrier gas within the crystal structure. Therefore this design of etching gas supply system 37 reduces the opportunity for carrier gas channels to form and so increases the efficiency and uniformity of the supply of XeF₂ gas to the process chamber 11.

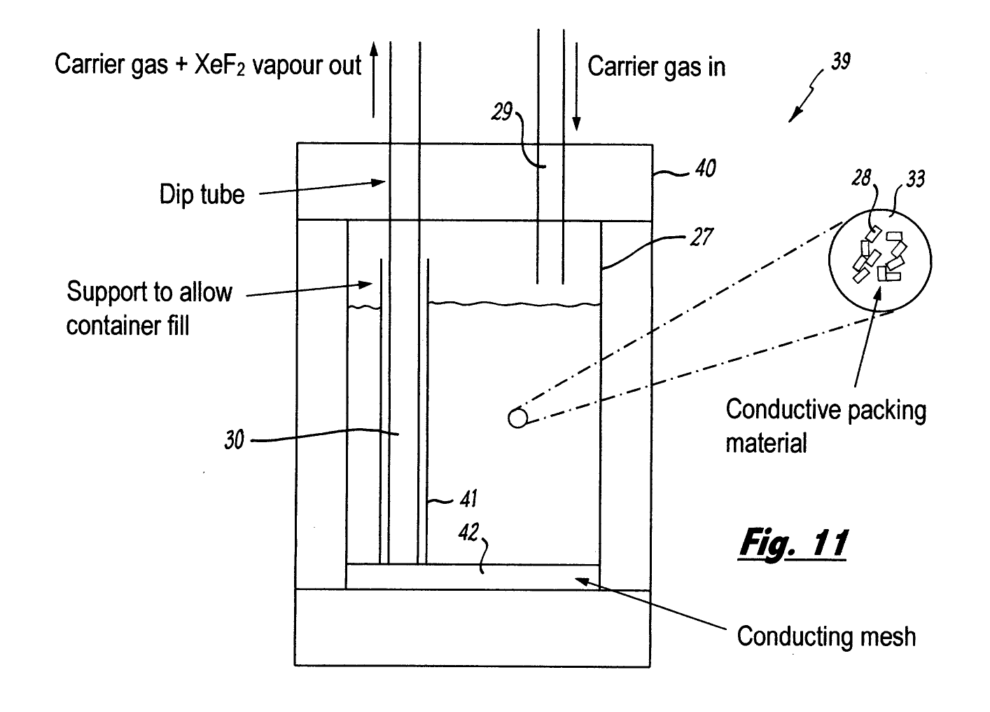

FIG. 11 presents a further alternative embodiment of etching gas supply system 39. As can be seen the etching gas supply system 39 comprises many of the features of the etching gas supply system 32 presented in FIG. 8, namely:
1) a sealed chamber 27 that comprises the XeF₂ crystals 28 and the packing material 33;
2) an entrance conduit 29 that penetrates down through the XeF₂ crystals 28; and
3) an exit conduit 30 that is located above the surface of the XeF₂ crystal 28.

In addition to the above features the etching gas supply system 39 further comprises a lid 40 that is removable from the sealed chamber 27 so as to facilitate the filling and removal of material processes. The lid 40 is sealed to the chamber 27 via an O-ring.

Located within the chamber 27 is an entrance conduit support tube 41 that descends to the base of the chamber 27 so as to locate with a thermally conducting mesh support 42. The mesh support 42 is employed so as to allow even access of carrier gas XeF₂ vapour, to the exit conduit 30, to the volume located below the XeF₂ crystals 28. This arrangement results in a reduction of the effect of channelling within the XeF₂ crystal 28. The presence of entrance conduit support tube 41 means that as the chamber 27 is filled with material a space is always reserved for the entrance conduit 29 to be inserted.

In the presently described embodiment the walls of the chamber 27 are made of a transparent material. This allows for the observation of the precursor and packing material so allowing useful information to be gathered on the gas dynamics and usage profile within the chamber 27. Furthermore, the employment of transparent walls allows for detectors to be employed so as to automatically detect the material usage within the container.

This can be achieved optically by using a light source 46, such as an LED or laser, mounted on the side of the chamber 27 with the emitted light impinging on a detector 47 mounted on the opposite side to detect the transmission through the chamber 27. Alternatively the detector 47 could be mounted at some other position where it can detect the reflected beam from the contents of the chamber 27. This arrangement could be used as a level detector to detect the level of crystals 28 within the chamber 27.

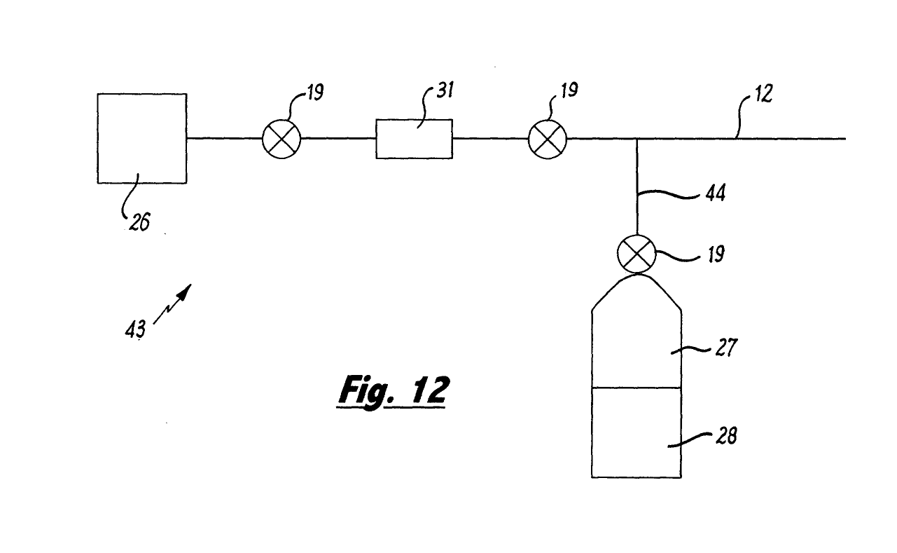

A yet further alternative of etching gas supply system 43 is now described with reference to FIG. 12. In this embodiment the sealed chamber 27 is connected to the first gas supply line 12 by a single conduit 44. During operation the pressure within the sealed chamber 27 is maintained at approximately 4 Torr. The helium carrier gas is then caused to flow through the first gas supply line 12 at a pressure of less than 4 Torr. As a result the XeF₂ gas within the sealed chamber 27 is drawn by the carrier gas into the first supply line 12 and thereafter transported to the process chamber 11, as required. Continued sublimation of the XeF₂ crystals 28 within the sealed chamber 27 acts to maintain the required XeF₂ gas so resulting in a continuous and uniform supply of XeF₂ gas to the process chamber 11 as long as the helium gas remains at a pressure below ˜4 Torr.

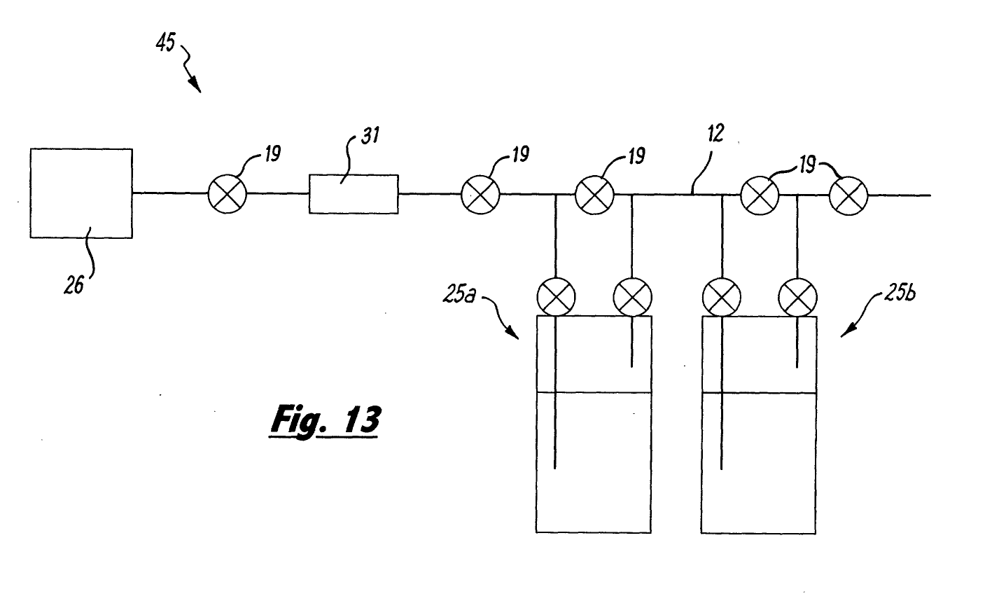

FIG. 13 presents a yet further alternative embodiment of the etching gas supply system of FIG. 4, depicted generally at 45 which again provides a more uniform supply of XeF₂ gas to the process chamber 11. In this particular embodiment two etching gas supply systems 25a and 25b are located in sequence within the first gas supply line 12. With this set up the helium carrier gas is initially propagated through the first etching gas supply system 25a and then subsequently through the second etching gas supply system 25b so as to ensure that the carrier gas is saturated with XeF₂ vapour. The first etching gas supply system 25a is thus preferentially depleted of XeF₂ crystals 28 while the second etching gas supply system 25b maintains the level of XeF₂ gas being carried to the process chamber 11 throughout the lifetime of the first etching gas supply system 25a.

When the first etching gas supply system 25a is depleted the valves 19 are closed such that the first etching gas supply system 25a can be removed from the apparatus. The second etching gas supply system 25b is then shifted from its original position to the position of the first etching gas supply system 25a. A new full etching gas supply system is then installed at the original second etching gas supply systems position. The valves 19 are then reopened and production of XeF₂ gas continues as previously described. In practice the volume of XeF₂ crystals 28 contained within the etching gas supply system 45 allow the apparatus to operate for several hundred hours before the described replacement method is required to be implemented.

The above described apparatus has been described with reference to XeF₂ etching vapour and a helium carrier gas. However it is known that alternative etching vapours and carrier gases may equally well be employed without departing from the scope if the invention. For example the etching material can comprises any noble gas fluoride e.g. krypton difluoride, xenon tetrafluoride and xenon hexafluoride. Alternatively the etching material can comprises a halogen fluoride e.g. bromine trifluoride, chlorine trifluoride or iodine pentafluoride.

Similarly the carrier gas can comprise any of the inert gases. An alternative to the inert gases that can also be employed is nitrogen gas.

As a further alternative two or more of the above mentioned etching vapours or carrier gases may be employed in combination within the described apparatus.

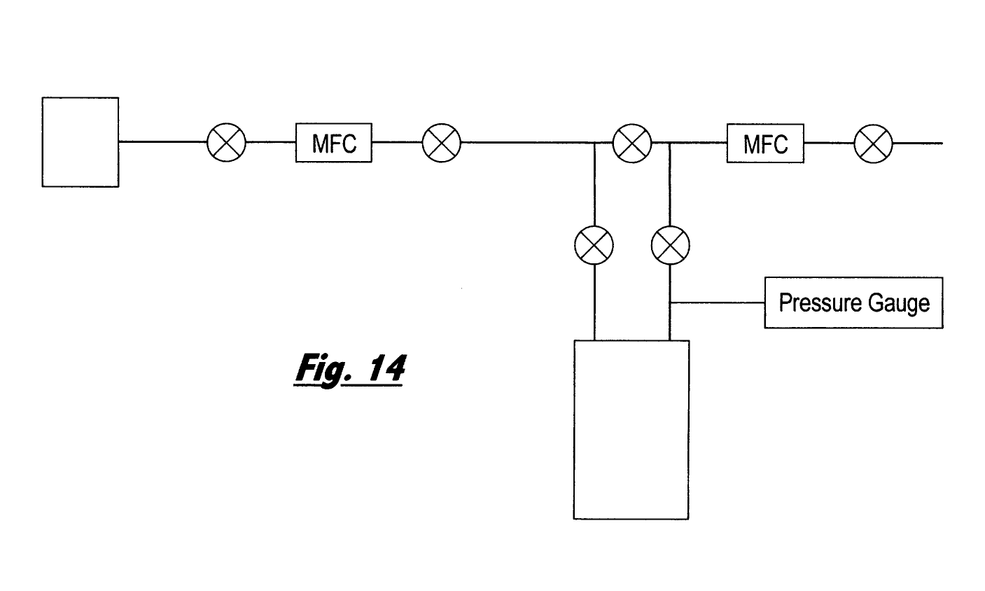

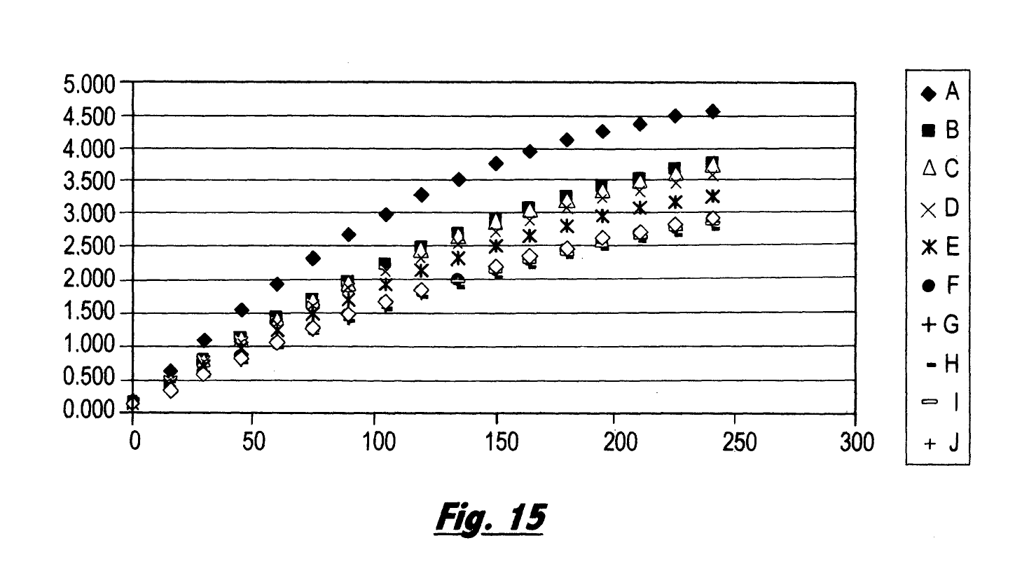

FIG. 14 presents a schematic representation of a pressurised carrier gas source 48. The pressure in the source chamber 49 with only XeF₂ crystals 50 present will rise to the vapour pressure at the temperature of the chamber 49 (i.e. ˜4 Torr at 25° C.). When flowing gases it is desirable to control the flow with a mass flow controller (MFC), however at low pressure differentials it is difficult to achieve accurate control.

The source chamber 49 can be pressurised using another gas, for example an inert gas such as helium. The amount of the pressurising gas 51 being added to the chamber 49 can be controlled by an MFC 52, while monitoring the pressure with a pressure gauge 53. Different amounts of gas 51 flowing into the chamber 49 results in variations in the XeF₂ gas mixture concentration.

With no output flow the partial pressure of the XeF₂ will equalise at the vapour pressure.

With an increased source chamber pressure a further MFC 54 on the output line 55 can be used to accurately control the amount of gas mixture leaving the source chamber 49 and flowing to the process chamber 11.

As the gas mixture leaves the source chamber 49 the partial pressure of the XeF₂ will drop and sublimation will increase to re-establish the vapour pressure. By analysing the flow of the pressurizing gas 51, the source chamber pressure and the flow of the gas mixture leaving the source chamber 49, careful process control can be established.

Maintaining a higher pressure in the source chamber 49 allows accurate control of the gas flow to the process chamber 11 using an MFC 54.

Stopping flow of the carrier gas 51 and opening the output valve 56 of the source chamber 49, XeF₂ gas flows to the processing chamber 11. The gas can be pumped away from and through the process chamber 11 by a vacuum pump 17. The chamber pressure will be an indication of the amount of XeF₂ flowing into the process chamber 11. The amount of XeF2 flow is an indication of the sublimation rate of the XeF2 crystals 50 in the source chamber 49. The sublimation rate is dependent on various parameters including primarily the amount of XeF2 crystals 50 present in the source chamber 49, the temperature of the crystals, the crystal size and density and the geometry of the chambers 11, 49. Determining the sublimation rate gives a direct indication of the amount of XeF₂ crystals 50 remaining in the source chamber 49. This can be used to monitor the XeF2 consumption and indicate when the source chamber 49 requires to be replaced or refilled.

Closing the valve to the vacuum pump 17 stops the gas flowing out of the process chamber 11 and the pressure begins to rise determined by the amount of XeF₂ gas flowing into the process chamber 11. The process chamber pressure rise can be monitored and is normally referred to as a rate of rise. The amount of gas flowing is determined by the sublimation rate of the XeF2 crystals 50 in the source chamber 49. The pressure in the chamber will rise in a distinctive way, as shown in the graph 57 FIG. 4. Initially the rate of rise will be fast and then as the chamber pressure increases the rate of rise will decrease. The rate of rise will then tend towards zero as the chamber pressure tends towards the vapour pressure of the XeF2. The speed of the rate of rise and the changes monitored will be directly determined by the XeF2 gas flow which in turn is determined by the sublimation rate of the XeF2 crystals 50. This can also be used to monitor the XeF2 consumption and indicate when the source chamber 49 requires to be replaced or refilled.

Such a technique can be used to monitor the gas flow as a result of sublimation from any solid or vaporization from any liquid to determine the amount of material remaining in a closed source chamber 49.

In the embodiment shown in FIG. 16, a mass flow meter (MFM) 58 is used to monitor the gas flow output from the source chamber 49. The measured flow is a combination of the carrier gas flow and the XeF2 gas flow. The carrier gas flow is known as it is controlled by the MFC 52 on entry to the source chamber 49. Subtracting this flow from the MFM reading and using the appropriate correction factor for the MFM 58 the XeF2 gas flow can be determined.

To maintain a consistent XeF2 gas flow, changes can be made automatically by having the MFM reading and the MFC control as part of a feedback loop controlled by system software.

Changes to the XeF2 gas flow with respect to the carrier gas flow can be used to determine the drop-off in XeF2 and the amount of XeF2 crystals 50 present in the source chamber 49. This provides yet another alternative method of monitoring the XeF2 consumption to determine when the source chamber 49 is required to be replaced or refilled.

Constantly monitoring the XeF2 gas flow allows the amount of XeF2 leaving the source chamber 49 to be determined. This again can be used to monitor the XeF2 usage. Keeping a cumulative record of the usage and comparing with a starting value can therefore also be used to indicate when the source chamber is required to be replaced or refilled.

In a single source chamber 49 based apparatus 48, as the XeF2 crystals 50 are consumed to a level where the amount of crystals remaining are insufficient to saturate the carrier gas flow, the amount of XeF2 vapour picked up by the carrier gas 51 drops with respect to the amount of XeF2 crystals 50 remaining in the source chamber 49. The MFM 58 on the output line 55 from the source chamber will measure the flow and analysis will detect changes in the XeF2 flow and therefore determine changes in pick-up.

To compensate for the drop-off in XeF2 pick-up the carrier gas flow can be increased. However this changes the gas flow and hence etch material vapour concentration in the process chamber 11. To maintain a consistent gas flow and concentration to the process chamber 11 another gas line 59 is used to compensate for the change necessitated in the output line 55.

As the flow of carrier gas to the source chamber 49 is increased to adjust to the drop in XeF2 pick-up the gas supply 60 in the additional line 59 is reduced by the same amount using the additional MFC 54 so that the gas supply to the process chamber 11 is maintained with respect to gas flow and mixture concentration.

The initial gas flow in the additional line 59 needs to be high enough to allow for the increase in the carrier gas flow to compensate for the XeF2 flow. The additional gas line 59 is preferably flowing the same gas as is in the carrier gas line.

The above described apparatus provides a number of significant advantages over those etching gas sources, and related systems, described in the prior art. In the first instance the use of an etching gas supply system allows for a controlled continuous supply of the etching gas to be provided to the process chamber. It is appreciated by those skilled in the art that the cost of XeF₂ crystals has reduced significantly in recent years thus making a move towards a continuous flow system significantly more favourable than previously considered.

Employment of the described apparatus results in a continuous flow system that maintains the partial pressure of the etching vapour the maximum partial pressure (˜4 Torr at room temp for XeF₂) throughout the etching process. This pressure is maintained as long as there is enough XeF₂ crystals to provide the vapour at the flow rate required. Thus, the present invention provides the maximum etching rate achievable and maintains this rate throughout the etching process i.e. there is no drop off in the etching rate as experienced by the prior art systems.

A yet further advantage is that by employing a low pumping rate within the system the residence time of the etching vapour within in the process chamber can be maximised. In practice, the pumping rate is set so as to optimise the residence time of the XeF₂ vapour within the process chamber and to remove the etching by-products thus maximising the etching rate with a minimal consumption of XeF₂ crystals.

A further advantage of the described apparatus is that it does not require the incorporation of any expansion chambers or other complicated mechanical features in order to achieve the continuous flow of etching gas. Therefore, the presently described apparatus is of a significantly simpler design and so is more cost effective to produce and operate than those systems described within the prior art.

The foregoing description of the invention has been presented for purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated.

Therefore, further modifications or improvements may be incorporated without departing from the scope of the invention.

1. An etching gas source for etching one or more microstructures located within a process chamber, the etching gas source comprising:
a gas source supply line connected to a carrier gas source; and
one or more chambers adapted to contain an etching material;
wherein the one or more chambers transform the etching material into an etching material vapour, and the gas supply line provides a path for supplying a the carrier gas to the etching material vapour and thereafter for supplying the etching material vapour transported by the carrier gas to the process chamber.

2. The etching gas source as described in claim 1 wherein the etching material is solid when under standard state conditions.

3. The etching gas source as described in claim 1 wherein the etching material is liquid when under standard state conditions.

4. The etching gas source as described in claim 1 wherein the carrier gas also functions as a coolant for the etching of the one or more microstructures within the process chamber.

5. The etching gas source as described in claim 1 wherein the etching gas source further comprises a temperature controller for controlling the temperature of the etching gas source.

6. The etching gas source as described in claim 1 wherein the etching gas source further comprises a temperature controller for controlling the temperature of the one or more chambers.

7. (canceled)

8. The etching gas source as described in claim 1 wherein the one or more chambers comprise a meshed frame suitable for supporting the etching material and which defines a sub-chamber area located below the etching material.

9. The etching gas source as described in claim 1 wherein the one or more chambers comprises a first conduit that couples the one or more chambers to the gas supply line.

10. The etching gas source as described in claim 9 wherein the one or more chambers further comprise a second conduit that couples the one or more chambers to the gas supply line.

11. The etching gas source as described in claim 9 wherein one end of the first conduit is located within the one or more chambers so that the carrier gas is supplied directly above a first surface of the etching material.

12. The etching gas source as described in claim 9 wherein the end of the first conduit is located within the sub-chamber.

13. The etching gas source as described in claim 10 wherein one end of the second conduit is located within the one or more chambers so that the carrier gas is supplied directly below the first surface of the etching material.

14. The etching gas source as described in claim 10 wherein one end of the second conduit is located within the sub-chamber.

15. The etching gas source as described in claim 9 wherein the apparatus further comprises a conduit support tube that provides a channel for locating the first conduit within the one or more chambers.

16. The etching gas source as described in claim 1 wherein the etching gas source further comprises a plurality of artificial voids that act to increase the surface area between the carrier gas and the etching material.

17. The etching gas source as described in claim 16 wherein the artificial voids comprises a plurality of packing materials.

18. The etching gas source as described in claim 17 wherein the packing materials comprises materials of good thermal conductivity.

19. The etching gas source as described in claim 17 wherein the packing materials comprises polytetrafluoroethylene.

20. The etching gas source as described in claim 17 wherein the packing materials comprises stainless steel.

21. The etching gas source as described in claim 16 wherein the artificial void comprises a preformed insert.

22. The etching gas source as described in claim 1 wherein the etching gas source further comprises one or more mechanical vibrators that provides a means for vibrating the one or more chambers.

23. The etching gas source as described in claim 8 wherein the first conduit comprises a flexible pipes.

24. The etching gas source as described in claim 1 wherein the one or more chambers comprises one or more substantially tangential entrance conduits each of which are coupled to the gas source supply line so as to provide a path for allowing the carrier gas to physically stir the etching material.

25. The etching gas source as described in claim 1 wherein the apparatus comprises two or more chambers connected together in series.

26. The etching gas source as described in claim 25 wherein the etching material saturates the carrier gas before being supplied to the process chamber.

27. The etching gas source as described in claim 1 wherein the etching material comprises a noble gas fluoride.

28. The etching gas source as described in claim 27 wherein the noble gas fluoride is selected from a group comprising krypton difluoride and the xenon fluorides.

29. The etching gas source as described in claim 1 wherein the etching material comprises a halogen fluoride.

30. The etching gas source as described in claim 29 wherein the halogen fluoride is a member selected from a group comprising bromine trifluoride, chlorine trifluoride and iodine pentafluoride.

31. The etching gas source as described in claim 1 wherein the carrier gas comprises an inert gas.

32. The etching gas source as described in claim 31 wherein the inert gas is helium.

33. The etching gas source as described in claim 1 wherein the carrier gas is nitrogen.

34. The etching gas source as described in claim 1 wherein the supply of the carrier gas to the chamber is controlled by one or more mass flow control devices.

35. The etching gas source as described in claim 34 wherein the supply of the carrier gas to the chamber is further controlled by one or more valves.

36. A gas phase etching apparatus comprising:
a process chamber suitable for locating one or more microstructures; and
an etching gas source as described in claim 1.

37. The gas phase etching apparatus as described in claim 36 wherein the etching gas source is located within an input line to the process chamber.

38. The gas phase etching apparatus as described in claim 37 wherein the gas phase etching apparatus further comprises a vacuum pump located within an output line from the process chamber that provides a means for creating and maintaining a vacuum within the process chamber.

39. The gas phase etching apparatus as described in claim 36 further comprises a pressure gauge coupled to the process chamber.

40. The gas phase etching apparatus as described in claim 37 wherein the gas phase etching apparatus further comprises a gas vent located within the input line to the process chamber.

41. The gas phase etching apparatus as described in claim 37 wherein the gas phase etching apparatus further comprises one or more additional fluid supply lines connected to the input line.

42. The gas phase etching apparatus as described in claim 41 wherein the one or more additional fluid supply lines are connected to the vacuum pump.

43. A method of etching one or more microstructures located within a process chamber, the method comprising the steps of:
a) transforming an etching material from a first state into an etching material vapour; and
b) supplying a carrier gas to the process chamber via the etching material vapour so allow for the transportation of the etching material vapour to the process chamber.

44. The method as described in claim 43 wherein the step of supplying the carrier gas to the process chamber via the etching material vapour is repeated to ensure that the carrier gas is saturated with the etching material vapour.

45. The method as described in claim 43 wherein the transformation of the etching material comprises the sublimation of the etching material from a first state that is solid.

46. The method as described in claim 43 wherein the transformation of the etching material comprises the vaporisation of the etching material from a first state that is liquid.

47. The method as described in claim 43 wherein the carrier gas also functions as a coolant for the etching of the one or more microstructures within the process chamber.

48. The method as described in claim 43 wherein the efficiency of the transportation of the etching material vapour by the carrier gas is increased by the addition of artificial mechanical voids to the etching material.

49. (canceled)

50. The method as described in claim 48 wherein the artificial mechanical voids create multiple pathways that the carrier gas may propagate through such that the area of contact between the carrier gas and the etching material is increased.

51. The method as described in claim 43 wherein the efficiency of the transportation of the etching material vapour by the carrier gas is increased by agitating the etching material.

52. The method as described in claim 43 wherein the efficiency of the method of etching is increased by heating the etching material so as to maintain the material at a constant predetermined temperature.

53. The method as described in claim 43 wherein a partial pressure of the etching material vapour within the process chamber is maintained below a vapour pressure of the etching material.

54. The method as described in claim 53 wherein the partial pressure of the etching material vapour is increased by increasing the temperature of the etching material.

55. The method as described in claim 53 wherein the rate at which the etching occurs is increased by increasing the partial pressure of the etching material vapour within the process chamber.

56. The method as described in claim 43 wherein the method comprises the additional step of selecting a partial pressure of etching material vapour in the process chamber in response to the size of the one or more microstructures to be etched.

57. The method as described in claim 43 wherein the rate at which the etching material vapour is supplied to the process chamber is selected in response to a desired etch rate and a rate of removal of etching material vapour from the process chamber.

58. The method as described in claim 43 wherein the method comprises the additional step of providing a breakthrough step in which a native oxide layer is etched.

59. The method as described in claim 58 wherein the breakthrough step comprises adding a fluid selected to react with the etching material vapour in the process chamber, the product of which etches the native oxide layer.

60. The method as described in claim 59 wherein the breakthrough step comprises decomposing XeF₂ using an energy source such as plasma, ion beam or UV light.

61. The method as described in claim 43 wherein the method further comprises the additional steps of:
a). preventing the supply of carrier gas;
b). employing a vacuum pump to pump the etching material vapour to the process chamber; and
c). measuring the pressure in the process chamber;
wherein measuring the pressure in the process chamber provides a means of determining the amount of etch material in a source chamber.

62. The method as described in claim 61 wherein the amount of etch material in the source chamber is determined by determining the sublimation rate of the etch material.

63. The method as described in claim 43 wherein the method further comprises the steps of:
a). preventing gas flow out of the process chamber;
b). monitoring the rise in pressure in the process chamber; and
c). determining the rate of rise in pressure in the process chamber;
wherein determining the rate of rise of pressure provides a means of monitoring the consumption of etch material in a source chamber.

64. The method as claimed in claim 43 comprising the additional steps of:
a). measuring the carrier gas flow to the source chamber;
b). measuring the total mass flow of etching material vapour and carrier gas leaving the source chamber; and
c). determining the etch material vapour flow from the total mass flow and the carrier gas flow;
wherein determining the etch material vapour flow provides a means of feedback to control the carrier gas flow in order to provide a controlled supply of etch material vapour to the process chamber.

65. The etching gas source as described in claim 10 wherein the second conduit comprises a flexible pipe.
